(19) United States
(12) Patent Application Publication
(10) Pub. No.: US 2024/0190702 A1
(43) Pub. Date: Jun. 13, 2024

(54) SEMICONDUCTOR COMPONENT AND METHOD FOR MANUFACTURING A SEMICONDUCTOR COMPONENT

(71) Applicant: Robert Bosch GmbH, Stuttgart (DE)

(72) Inventors: Gregor Schuermann, Reutlingen (DE); Pascal Gieschke, Reutlingen (DE)

(21) Appl. No.: 18/534,658

(22) Filed: Dec. 10, 2023

(30) Foreign Application Priority Data
Dec. 12, 2022 (DE) 102022213418.4

(51) Int. Cl. B81C 1/00

(52) U.S. Cl. CPC B81C 1/00833; B81C 2201/0171; B81C 2201/0177

(57) ABSTRACT

A semiconductor component. The semiconductor component has a semiconductor substrate, an insulation layer, and a first monocrystalline silicon layer. The insulation layer is arranged on the semiconductor substrate, and the first monocrystalline silicon layer is arranged on the insulation layer and at least one first region that extends starting from the first monocrystalline silicon layer up to a surface of the semiconductor substrate. The at least one first region includes second monocrystalline silicon.

### FIELD

The present invention relates to a semiconductor component and a method for manufacturing a semiconductor component.

### BACKGROUND INFORMATION

In the manufacture of integrated circuits and MEMS elements, silicone-on-insulator substrates, so-called SOI substrates, are increasingly being used. As a result, ICs with low power consumption and high switching speeds, along with high-voltage circuits with insulated regions, can be manufactured in a very small space. Furthermore, the complexity of the MEMS processes can be reduced and the accuracy of MEMS sensors can be improved.

It is conventional to electrically and thermally connect the handling wafer to the device layer at the end of the manufacturing process. An opening up to the buried oxide is inserted into the cover layers produced up to that point. Doped polysilicon, for example, is subsequently deposited in the openings and contacted accordingly.

The disadvantage here is that the handling wafer can become charged in an undefined manner during the entire processing, especially during the dry etching processes, and can assume a high potential. In this way, functional disturbances or damage can occur in the components located in the device layer. Furthermore, it is disadvantageous that the device layer is thermally poorly connected to the handling wafer during the entire processing.

An object of the present invention is to overcome this disadvantage.

### SUMMARY

According to an example embodiment of the present invention, a semiconductor component comprises a semiconductor substrate, an insulation layer and a first monocrystalline silicon layer, wherein the insulation layer is arranged on the semiconductor substrate and the first monocrystalline silicon layer is arranged on the insulation layer, and at least one first region, which extends starting from the first monocrystalline silicon layer up to a surface of the semiconductor substrate. According to the present invention, the at least one first region comprises second monocrystalline silicon.

An advantage here is that both a thermal and an electrical connection is present between the semiconductor substrate and the first monocrystalline silicon layer, which is firmly bonded. In other words, both the mechanical and the electrical and the thermal connection guarantee a substrate contact that is stable over time.

In a further development of the present invention, the at least one first region is designed as an array having a plurality of connection regions that extend starting from the first monocrystalline silicon layer up to a surface of the semiconductor substrate, wherein the connection regions are filled with the second monocrystalline silicon.

It is advantageous here that the electrical resistance between the semiconductor substrate and the first monocrystalline silicon layer is low.

In a further embodiment of the present invention, the connection regions have round cross-sections.

In a further embodiment of the present invention, the connection regions have rectangular cross-sections.

In a further embodiment of the present invention, the connection regions have square cross-sections.

An advantage here is that the connection regions are easy to manufacture.

In a further development of the present invention, edges of the connection regions have an angle of 45° to a <110> crystal direction of the semiconductor substrate.

It is advantageous here that the surface topography of the contact hole region is low.

In a further embodiment of the present invention, the at least one first region has a lateral extension that is at least twice as large as a thickness of the insulation layer.

An advantage here is that there is a stable connection between the semiconductor substrate and the first monocrystalline silicon layer.

In a further embodiment of the present invention, the first monocrystalline silicon layer has second regions laterally with respect to the first region and the surface of the semiconductor substrate has second regions in the first region, wherein the second regions have the same doping type as the semiconductor substrate.

An advantage here is that the semiconductor substrate contact resistance is low.

A method according to an example embodiment of the present invention for manufacturing a semiconductor component having a semiconductor substrate, an insulation layer and a monocrystalline silicon layer, wherein the insulation layer is arranged on the semiconductor substrate and the first monocrystalline silicon layer is arranged on the insulation layer, and at least one first region, which extends starting from the first monocrystalline silicon layer up to a surface of the semiconductor substrate, comprises at least partially filling the at least one first region with a second monocrystalline silicon by means of epitaxy.

An advantage here is that the electrical and thermal connection between the semiconductor substrate and the first monocrystalline silicon layer, the so-called device layer, is produced at an early stage of the manufacturing process so that the semiconductor substrate or the semiconductor substrate wafer cannot become charged and damage the subsequently produced components. This also simplifies and improves the cooling of the wafer surface and prevents inhomogeneous temperature distribution across the wafer during the manufacturing process. Furthermore, the process is CMOS-compatible, and the wafers can be subsequently further processed by means of standard processes.

In a further development of the present invention, second regions are produced by means of ion implantation, wherein the second regions are arranged in the first monocrystalline silicon layer laterally with respect to the first region and on the surface of the semiconductor substrate in the first region, wherein the second regions have the same doping type as the semiconductor substrate.

An advantage here is that the contact resistance between the semiconductor substrate and the first monocrystalline silicon layer is low due to the consistently high doping in the contact hole region.

Further advantages can be found in the following description of exemplary embodiments and the rest of the disclosure herein.

### BRIEF DESCRIPTION OF THE DRAWINGS

The present invention is explained below with reference to preferred embodiments and the figures.

FIG. 1 shows a semiconductor component according to an example embodiment of the present invention.

FIG. 2 shows a method for manufacturing a semiconductor component, according to an example embodiment of the present invention.

### DETAILED DESCRIPTION OF EXAMPLE EMBODIMENTS

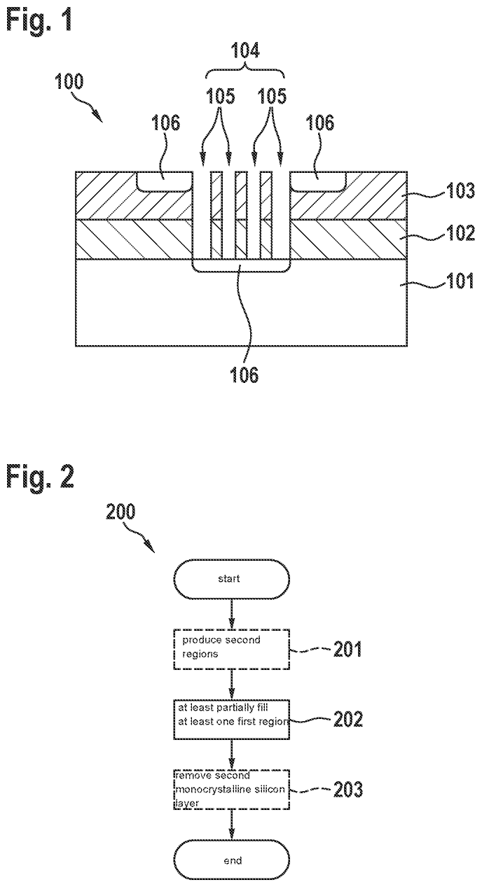

FIG. 1 shows a semiconductor component 100 according to the present invention having a semiconductor substrate 101 on which an insulation layer 102 is arranged. A first monocrystalline silicon layer 103 is arranged on the insulation layer 102. The semiconductor substrate 101, the insulation layer 102 and the first monocrystalline silicon layer 103 form a so-called SOI wafer. The semiconductor component 100 has at least one first region 104 that extends starting from the first monocrystalline silicon layer 103 up to a surface of the semiconductor substrate 101. The at least one first region 104 comprises a second monocrystalline silicon. The first monocrystalline silicon layer 103 and the second monocrystalline silicon have an identical crystal orientation. However, with respect to doping, the first monocrystalline silicon layer 103 and the second monocrystalline silicon can be designed differently. The at least one first region 104 has a lateral extension that is at least twice as large as a thickness of the insulation layer 102. In other words, the contact hole diameter must be at least twice as large as the thickness of buried insulation layer 102, so that a connection arises between the semiconductor substrate 101 and the first monocrystalline silicon layer 103, the so-called device layer. The at least one first region 104 has in particular a lateral extension or a diameter that is five to six times wider than the thickness of the insulation layer 102. The insulation layer 102 comprises, for example, an oxide layer or a nitride layer.

In one exemplary embodiment, the at least one first region 104 is completely filled with the second monocrystalline silicon, so that the semiconductor substrate 101 and the first monocrystalline silicon layer 103 are mechanically, electrically and thermally connected to one another.

In a further exemplary embodiment, the at least one first region 104 is designed as an array with a plurality of connection regions 105. The connection regions 105 extend starting from the first monocrystalline silicon layer 103 up to a surface of the semiconductor substrate 101. The connection regions 105 are filled with the second monocrystalline silicon. The connection regions 105 have round, rectangular or square cross-sections. In the case of a square geometry, it is advantageous if edges of the connection regions 105 have an angle of 45° to a <110> crystal direction of the semiconductor substrate 101. In addition, in both exemplary embodiments, second regions 106 can be arranged laterally with respect to the first region 104 in the first monocrystalline silicon layer 103 and in the first region 104 on the surface of the semiconductor substrate 101. The second regions 106 are designed like a trough, wherein the second regions 106 have the same doping type as the semiconductor substrate 101. In the case of p-doping, for example, boron is used, and in the case of n-doping, for example, phosphorus, antimony or arsenic are used. This doping enables a low-impedance contact between the semiconductor substrate 101 and the first monocrystalline silicon layer 103. It furthermore enables contact between the semiconductor substrate 101 and the first monocrystalline silicon layer 103 if the second monocrystalline silicon has a different dopant than the first monocrystalline silicon layer 103. The doping introduced must be sufficiently strong to redope the upper silicon layer.

The semiconductor substrate 101 typically has a thickness of several 100 μm. The insulation layer 102 or insulator layer has a thickness of between 100 nm and 2 μm. The first monocrystalline silicon layer 103, the component layer or the so-called device layer, also has a thickness of between 100 nm and 2 μm.

The semiconductor components 100 can be designed as integrated circuits, MEMS sensors, integrated MEMS sensors or differential pressure sensors.

FIG. 2 shows the method 200 according to the present invention for manufacturing a semiconductor component having a semiconductor substrate, an insulation layer and a first monocrystalline silicon layer, wherein the insulation layer is arranged on the semiconductor substrate and the first monocrystalline silicon layer is arranged on the insulation layer, and at least one first region that extends starting from the first monocrystalline silicon layer up to a surface of the semiconductor substrate. The method 200 starts with the step 202, in which the at least one first region is at least partially filled with a second monocrystalline silicon by means of epitaxy. In other words, it is a monocrystalline epitaxial step. A thermal and electrical connection is produced by means of monocrystalline silicon. For this purpose, the second monocrystalline silicon grows from the at least one first region over the first monocrystalline silicon layer, so that the first silicon layer is covered by a second monocrystalline silicon layer. The layer thickness of the second monocrystalline silicon layer can be selected such that it can be used for further processing of the components. This means that the thermal and electrical connection between the semiconductor substrate and the first monocrystalline silicon layer is produced within the normal process sequence, i.e., during the frontside process, wherein no additional process step is necessary.

In an optional step 203, the second monocrystalline silicon layer can be removed up to the surface of the first monocrystalline silicon layer or up to a certain layer thickness of the second monocrystalline silicon layer by means of CMP. As a result, the unevenness produced as a result of the insulation layer thickness, the thickness of the first monocrystalline silicon layer, the thickness of the second monocrystalline silicon layer or the epitaxial conditions and the cross-section of the at least one first region or produced by the cross-sections of the connection regions is removed above the first monocrystalline silicon layer, since the unevenness can have a disturbing effect for the further manufacturing process.

Optionally, in a step 201, which is carried out prior to the step 202, second regions are produced in the first monocrystalline silicon layer laterally with respect to the first region and on the surface of the semiconductor substrate in the first region by means of ion implantation, wherein the second regions have the same doping type as the semiconductor substrate. During epitaxy in the step 202, the dopants of the trough-like doped regions grow with the second monocrystalline silicon, since at the high temperatures necessary for epitaxy, the introduced dopants are mobilized and move.

Alternatively, a highly doped epitaxial step can be carried out for producing the second monocrystalline silicon.

1-10. (canceled)

11. A semiconductor component, comprising:
a semiconductor substrate;
an insulation layer; and
a first monocrystalline silicon layer, wherein the insulation layer is arranged on the semiconductor substrate and the first monocrystalline silicon layer is arranged on the insulation layer, and at least one first region that extends starting from the first monocrystalline silicon layer up to a surface of the semiconductor substrate;
wherein the at least one first region includes a second monocrystalline silicon.

12. The semiconductor component according to claim 11, wherein the at least one first region is an array with a plurality of connection regions that extend starting from the first monocrystalline silicon layer up to the surface of the semiconductor substrate, wherein the connection regions are filled with the second monocrystalline silicon.

13. The semiconductor component according to claim 12, wherein the connection regions have a round cross-section.

14. The semiconductor component according to claim 12, wherein the connection regions have a rectangular cross-section.

15. The semiconductor component according to claim 12, wherein the connection regions have a square cross-section.

16. The semiconductor component according to claim 15, wherein edges of the connection regions have an angle of 45° to a <110> crystal direction of the semiconductor substrate.

17. The semiconductor component according to claim 11,
wherein the at least one first region has a lateral extension that is at least twice as large as a thickness of the insulation layer.

18. The semiconductor component according to claim 11, wherein the first monocrystalline silicon layer has second regions laterally with respect to the first region, and the surface of the semiconductor substrate has second regions in the first region, wherein the second regions have the same doping type as the semiconductor substrate.

19. A method for manufacturing a semiconductor component having a semiconductor substrate, an insulation layer and a monocrystalline silicon layer, wherein the insulation layer is arranged on the semiconductor substrate, and the first monocrystalline silicon layer is arranged on the insulation layer and at least one first region, which extends starting from the first monocrystalline silicon layer up to a surface of the semiconductor substrate, the method comprising the following steps:
at least partially filling the at least one first region with a second monocrystalline silicon by epitaxy.

20. The method according to claim 19, wherein second regions are produced by ion implantation, wherein the second regions are arranged in the first monocrystalline silicon layer laterally with respect to the first region and on the surface of the semiconductor substrate in the first region, wherein the second regions have the same doping type as the semiconductor substrate.
